(19) United States
(12) Patent Application Publication
(10) Pub. No.: US 2025/0069858 A1
(43) Pub. Date: Feb. 27, 2025

(54) PLASMA PROCESSING APPARATUS AND CONTROL METHOD THEREFOR

(71) Applicant: ULVAC, INC., Chigasaki-shi (JP)

(72) Inventors: Kenta DOI, Chigasaki-shi (JP); Toshiyuki NAKAMURA, Chigasaki-shi (JP); Yasuhiro MORIKAWA, Chigasaki-shi (JP); Kensuke AKAZAWA, Chigasaki-shi (JP); Daisuke HIRONIWA, Chigasaki-shi (JP)

(21) Appl. No.: 18/807,175

(22) Filed: Aug. 16, 2024

(30) Foreign Application Priority Data
Aug. 23, 2023 (JP) 2023-135893

(51) Int. Cl. H01J 37/32; H01J 37/09

(52) U.S. Cl. CPC H01J 37/32577; H01J 37/09; H01J 37/3244

(57) ABSTRACT

[Object] To provide a plasma processing apparatus capable of expanding an formation region of plasma generated on an upper electrode side to increase the processing speed and a control method therefor.

[Solving Means] A plasma processing apparatus according to an embodiment of the present invention includes a vacuum chamber, a substrate-supporting stage, a counter electrode, and a resonant circuit. The substrate-supporting stage is disposed inside the vacuum chamber and is connected to a first high-frequency power supply circuit that supplies a high-frequency power at a first frequency. The counter electrode is disposed in opposite to the stage and is connected to a second high-frequency power supply circuit that supplies a high-frequency power at a second frequency. The resonant circuit allows high-frequency current at the second frequency from the counter electrode to pass therethrough.

### CROSS-REFERENCE TO RELATED APPLICATION

This application claims the benefit of Japanese Application No. 2023-135893, filed Aug. 23, 2023, which is hereby incorporated by reference in its entirety.

### TECHNICAL FIELD

The present invention relates to a plasma processing apparatus, e.g., a dry etching apparatus, and a control method therefor.

### BACKGROUND ART

Capacitive coupling plasma vacuum processing apparatuses of vacuum processing apparatuses such as etching apparatuses are known. For example, Patent Literature 1 has disclosed an apparatus that performs plasma processing by applying a first high-frequency voltage to a lower electrode supporting a processing substrate and applying a second high-frequency voltage to an upper electrode with a gas-introducing mechanism to generate a capacitive coupling plasma.

### CITATION LIST

### Patent Literature

Patent Literature 1: Japanese Patent Application Laid-open No. 2013-225672

### DISCLOSURE OF INVENTION

### Technical Problem

This type of dual-frequency CCP plasma processing apparatus has a problem in that it is difficult for a formation region of the plasma generated on the upper electrode side due to the second high-frequency voltage to expand to the vicinity of the surface of the processing substrate, and therefore it cannot largely contribute to an increase in processing speed.

In view of such circumstances, it is an object of the present invention to provide a plasma processing apparatus capable of expanding an formation region of plasma generated on an upper electrode side to increase the processing speed and a control method therefor.

### Solution to Problem

A plasma processing apparatus according to an embodiment of the present invention includes a vacuum chamber, a substrate-supporting stage, a counter electrode, and a resonant circuit.

The substrate-supporting stage is disposed inside the vacuum chamber and is connected to a first high-frequency power supply circuit that supplies a high-frequency power at a first frequency.

The counter electrode is disposed in opposite to the stage and is connected to a second high-frequency power supply circuit that supplies a high-frequency power at a second frequency.

The resonant circuit allows high-frequency current at the second frequency from the counter electrode to pass therethrough.

Since this plasma processing apparatus includes the resonant circuit that allows the high-frequency current at the second frequency from the counter electrode to pass therethrough between the power supply line and a ground potential, impedance of plasma current flowing to the stage from the counter electrode decreases. Accordingly, the formation region of the plasma generated on the counter electrode side expands, and therefore the processing speed can increase.

The resonant circuit may be adjusted so that a resonant frequency between a substrate surface on the stage to the ground potential is the second frequency.

The resonant circuit may be an LC series resonant circuit including a coil and a capacitor.

The first high-frequency power supply circuit may include an impedance matching circuit that is connected to a first high-frequency power supply, a filter circuit that shields an input with the high-frequency power at the second frequency that is applied to the power supply line, and a voltage measurement part that is connected between the impedance matching circuit and the filter circuit and measures a high-frequency voltage that is output to the stage from impedance matching. In this case, the resonant circuit may be connected to the power supply line between the stage and the filter circuit.

The capacitor may be a variable capacitor capable of adjusting a capacitance value. In this case, the plasma processing apparatus may further include a control unit that controls a capacitance value of the capacitor so that a voltage value measured by the voltage measurement part becomes minimum.

The plasma processing apparatus may further include an earth shield provided between a peripheral surface of the counter electrode and an inner wall surface of the vacuum chamber. The second frequency may be a frequency higher than the first frequency.

The plasma processing apparatus may further include a gas supply line for supplying an etching gas or a gas for deposition into the vacuum chamber.

A control method for the above-mentioned plasma processing apparatus according to an embodiment of the present invention, the resonant circuit being an LC series resonant circuit including a coil and a variable capacitor, includes:
measuring a high-frequency voltage at the first frequency that is input to the stage; and
controlling a capacitance value of the variable capacitor so that the high-frequency voltage becomes minimum.

### Advantageous Effects of Invention

In accordance with the present invention, the formation region of the plasma generated on the upper electrode side expands, and therefore the processing speed can increase.

### BRIEF DESCRIPTION OF DRAWINGS

FIG. 1 A schematic side cross-sectional view showing a configuration of a plasma processing apparatus according to an embodiment of the present invention.

FIG. 2 A conceptual diagram describing a problem of the present invention.

FIG. 3 A block diagram showing a relationship between a first high-frequency power supply circuit and a resonant circuit in the plasma processing apparatus.

FIG. 4 A diagram describing actions of the plasma processing apparatus, which is an experimental result showing a relationship between a capacitance value of the resonant circuit and an etching rate and a voltage value at a first frequency.

FIG. 5 A diagram describing actions of the plasma processing apparatus, which is an experimental result showing a relationship between an etching rate and a second-high frequency source power.

### MODE(S) FOR CARRYING OUT THE INVENTION

Hereinafter, an embodiment of the present invention will be described with reference to the drawings.

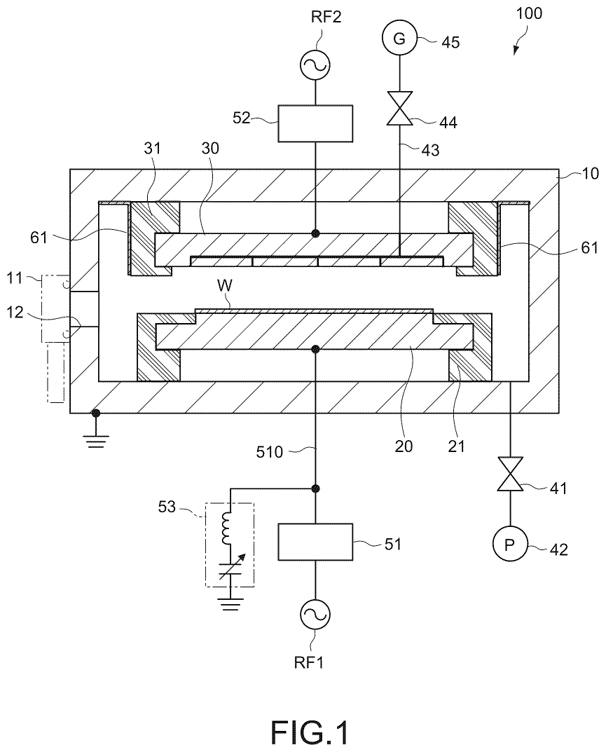

FIG. 1 is a schematic side cross-sectional view showing a configuration of a plasma processing apparatus 100 according to an embodiment of the present invention. The plasma processing apparatus 100 according to the present embodiment is configured as a dual-frequency CCP dry etching apparatus including a vacuum chamber 10, a stage 20 serving as a lower electrode, and a counter electrode 30 serving as an upper electrode.

The vacuum chamber 10 is a hermetically-sealed container that is connected to a vacuum pump 42 through an evacuation valve 41 and is capable of keeping a pressure-reduced atmosphere therein. The vacuum chamber 10 is made of metal and is connected to a ground potential. A side surface portion of the vacuum chamber 10 has an opening 12 opened/closed by a gate valve 11. A substrate is carried out of/into the vacuum chamber 10 through the opening 12.

The stage 20 is made of metal and is disposed inside the vacuum chamber 10. In the present embodiment, the stage 20 is provided in a bottom portion of the vacuum chamber 10 via a supporting member 21 made of an insulating material. An upper surface of the stage 20 is formed as a support surface for supporting a substrate W. The substrate W is a processing substrate such as a semiconductor wafer or a glass substrate. Although not shown in the figure, an electrostatic chuck mechanism that retains the substrate W and a temperature adjustment mechanism or the like that heats or cools the substrate W to a predetermined temperature may be provided on the stage 20.

The stage 20 is connected to a first high-frequency power supply circuit 51 provided outside the vacuum chamber 10. As it will be described later, the first high-frequency power supply circuit 51 includes an impedance matching circuit 511 connected to a first high-frequency power supply RF1 that generates high-frequency power at a first frequency (see FIG. 3). The first high-frequency power supply circuit 51 supplies the high-frequency power at the first frequency as a bias power to the stage 20. Although it is not particularly limited, for example, the first frequency is 2 MHz. Moreover, for example, the magnitude of the power is 500 W to 3000 W.

The counter electrode 30 is made of metal and is disposed in opposite to the stage 20. The counter electrode 30 is provided in a top plate portion of the vacuum chamber 10 via a supporting member 31 made of an insulating material. The counter electrode 30 is connected to a gas supply line 43. The counter electrode 30 has a function as a shower plate that uniformly injects a process gas to an entire surface region of the substrate W on the stage 20.

The gas supply line 43 is connected to a gas supply source 45 via a flow rate adjustment valve 44. In the present embodiment, the plasma processing apparatus 100 is configured as a dry etching apparatus, and therefore a reactant gas for etching (e.g., fluorine-based, hydrocarbon-based gas) is used as the process gas. It should be noted that the gas supply line 43 is not limited to that which is connected to the counter electrode 30, and the process gas may be supplied into the vacuum chamber 10 from a part of the side wall of the vacuum chamber 10, for example.

The counter electrode 30 is connected to a second high-frequency power supply circuit 52 provided outside the vacuum chamber 10. The second high-frequency power supply circuit 52 includes an impedance matching circuit connected to a second high-frequency power supply RF2 that generates high-frequency power at a second frequency. The second high-frequency power supply circuit 52 supplies the high-frequency power at the second frequency as an electric discharge power for generating plasma of the process gas to the counter electrode 30. Although it is not particularly limited, for example, the second frequency is 27 MHz. Moreover, for example, the magnitude of the power is 500 W to 4 kW.

In the present embodiment, the plasma processing apparatus 100 introduces the process gas (etching gas) into the vacuum chamber 10 via the gas supply line 43 and applies the high-frequency voltage from the second-frequency power supply RF2 to the counter electrode 30 with the inside of the vacuum chamber 10 kept in a predetermined pressure-reduced atmosphere, thereby generating plasma of the process gas (etching gas) between the stage 20 and the counter electrode 30. On the other hand, ions in the plasma are accelerated toward the substrate W on the stage 20 by applying the high-frequency voltage from the first high-frequency power supply RF1 to the stage 20. Accordingly, etching processing is performed on the surface of the substrate W. The processing pressure is, for example, 5 Pa to 30 Pa.

Here, this type of dual-frequency CCP plasma processing apparatus has a problem in that it is difficult for a formation region of the plasma generated on the upper electrode side due to the second high-frequency voltage to expand to the vicinity of the surface of the processing substrate, and therefore it is difficult to increase the processing speed (etching rate).

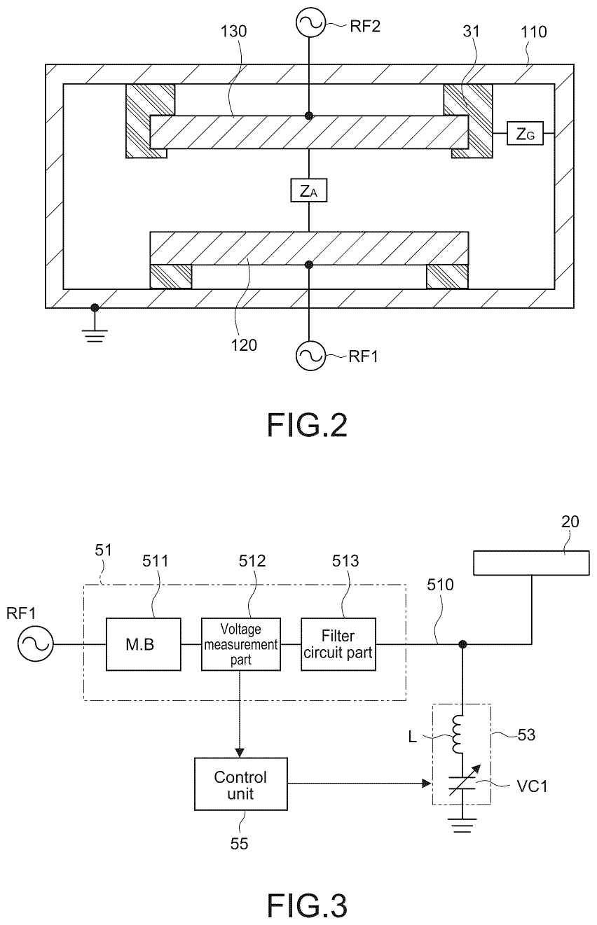

Such a problem can be caused by a part of the high-frequency voltage applied to the upper electrode 130 being consumed in electric discharge between the upper electrode 130 and an inner wall of a vacuum chamber 110 in the periphery thereof due to impedance Z_{A} between the upper electrode 130 and the lower electrode 120, which is significantly larger than impedance Z_{G} between the upper electrode 130 and the vacuum chamber 110 in the periphery thereof as conceptually shown in FIG. 2. As a result, the plasma formed between the upper electrode 130 and the lower electrode 120 does not sufficiently expand to the vicinity of the surface of the substrate on the lower electrode 120. Thus, an increase in the etching rate cannot be achieved.

In view of this, in the present embodiment, as shown in FIG. 1, a resonant circuit 53 that allows the high-frequency current at the second frequency from the counter electrode 30 to pass therethrough is connected between a power supply line 510 between the stage 20 and the first high-frequency power supply circuit 51 and the ground potential. By connecting the resonant circuit 53 between the stage 20 and the first high-frequency power supply circuit 51, the impedance between the counter electrode 30 and the stage 20 (corresponding to Z_{A} in FIG. 2) decreases and plasma current which flows in the stage 20 from the counter electrode 30 easily flows. Accordingly, the formation region of the plasma generated on the side of the counter electrode 30 expands, and therefore the processing speed (etching rate) can increase.

The resonant circuit 53 is an LC series resonant circuit including a coil L, which will be described later, and the capacitor VC1 (see FIG. 3), and an inductance value of the coil L and a capacitance value of a capacitor VC1 are adjusted so that a resonant frequency between the surface of the substrate W on the stage 20 to the ground potential becomes the second frequency (27 MHz). That is, the resonant circuit 53 is configured to resonate at the second frequency (27 MHz).

In addition, as shown in FIG. 1, the plasma processing apparatus 100 according to the present embodiment further includes an earth shield 61 provided between the peripheral surface of the counter electrode 30 and an inner side wall surface of the vacuum chamber 10. The earth shield 61 is formed of a tubular member made of metal, which is provided to cover the peripheral surface of the insulative supporting member 31 that covers the peripheral surface of the counter electrode 30. The earth shield 61 is attached to the vacuum chamber 10 and is connected to the ground potential via the vacuum chamber 10.

By providing the earth shield 61 in the periphery of the counter electrode 30 in this manner, a potential difference between the earth shield 61 and the inner side wall surface of the vacuum chamber 10 can be eliminated to suppress generation of electric discharge between the peripheral surface of the counter electrode 30 and the vacuum chamber 10. That is, impedance (Z_{G}) between the peripheral surface of the counter electrode 30 and the vacuum chamber 10 does not exist in appearance, and therefore the high-frequency voltage of the second frequency (27 MHz) applied to the counter electrode 30 is not consumed in electric discharge between the counter electrode 30 and the vacuum chamber 10 in the periphery thereof. Therefore, the whole high-frequency voltage applied to the counter electrode 30 is used to form the plasma between the counter electrode 30 and the stage 20, and therefore it can largely contribute to expansion of the plasma formation region to the vicinity of the surface of the substrate W.

It should be noted that in a manner that depends on needs, a similar earth shield may be provided in the periphery of the stage 20. In this case, electric discharge between the stage 20 due to the high-frequency voltage at the first frequency (2 MHz) applied to the stage 20 and the vacuum chamber 10 in the periphery thereof is suppressed. Also with such a configuration, it can contribute to the expansion of the plasma formation region to the vicinity of the surface of the substrate W.

Subsequently, the first high-frequency power supply circuit 51 and the resonant circuit 53 will be described in detail.

FIG. 3 is a block diagram showing a relationship between the first high-frequency power supply circuit 51 and the resonant circuit 53. As shown in the figure, the first high-frequency power supply circuit 51 includes the impedance matching circuit (matching circuit) 511, a voltage measurement part 512, and a filter circuit part 513.

The impedance matching circuit 511 is connected to the first high-frequency power supply RF1. The impedance matching circuit 511 is a circuit that makes the impedance of the first high-frequency power supply RF1, the impedance of the power supply line (transmission line path), and the impedance of the stage 20 (load) equal.

The voltage measurement part 512 measures a high-frequency voltage output to the stage 20 from the impedance matching circuit 511. The voltage measurement part 512 is connected between the impedance matching circuit 511 and the filter circuit part 513 and measures a peak-to-peak value (Vpp) of the high-frequency voltage at the first frequency (2 MHz).

The filter circuit part 513 is a circuit that shields an input of the high-frequency power at the second frequency (27 MHz) applied to the power supply line 510 from the counter electrode 30 via the stage 20. Accordingly, the first high-frequency power supply RF1, the impedance matching circuit 511, and the voltage measurement part 512 can be protected from the high-frequency power at the second frequency (27 MHz). Although it is not particularly limited, for example, the configuration of the filter circuit part 513 is constituted by a low-pass filter and a band-pass filter through which only the high-frequency power at the first frequency (2 MHz) can pass.

The resonant circuit 53 has the same resonant frequency as the frequency (second frequency) of the second high-frequency power supply RF2, which is applied to the counter electrode 30. In the present embodiment, the resonant circuit 53 is the LC series resonant circuit including the coil L and the capacitor VC1 and the capacitor VC1 is a variable capacitor having an adjustable capacitance value.

As described above, the resonant circuit 53 is connected between the power supply line 510 between the stage 20 and the first high-frequency power supply circuit 51 and the ground potential. Accordingly, the high-frequency power at the second frequency (27 MHz) (plasma current) that flows in the power supply line 510 can be made to flow toward the ground potential without inputting it to the first high-frequency power supply circuit 51, and therefore the impedance between the counter electrode 30 and the stage 20 (Z_{A}) can be reduced and the plasma formation region can be expanded to the vicinity of the surface of the substrate W while protecting the first high-frequency power supply circuit 51.

Here, the coil L that constitutes the resonant circuit 53 may include reactance components of various parts constituting the power supply line 510. In this case, an LC parallel resonant circuit in which the coil L is connected in parallel with the capacitor VC1 may constitute the resonant circuit 53, depending on the reactance components.

Moreover, in the present embodiment, the capacitance value of the capacitor VC1 is adjusted so that the high-frequency voltage (bias voltage) at the first frequency (2 MHZ) applied to the stage 20 becomes minimum. In the present embodiment, a control unit 55 that controls the capacitance value of the capacitor VC1 so that a voltage value measured by the voltage measurement part 512 becomes minimum is further provided.

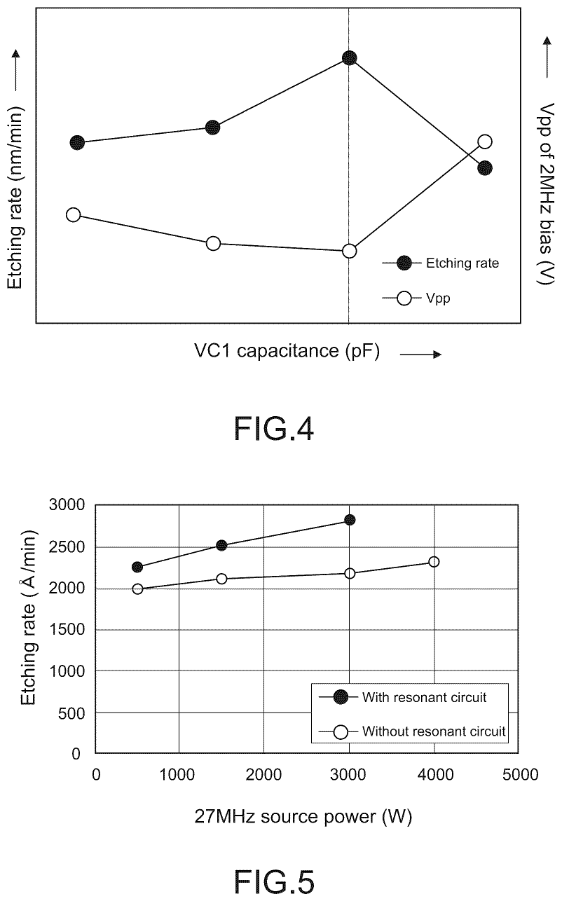

FIG. 4 is an experimental result showing a relationship between the capacitance value of the capacitor VC1 constituting the resonant circuit 53 and the etching rate and the voltage value Vpp at the first frequency (2 MHZ). As shown in the figure, the maximum etching rate can be obtained by adjusting the capacitance value of the capacitor VC1 so that the voltage value Vpp becomes minimum. Therefore, the substrate W can be processed with the etching rate kept at the maximum value in such a manner that the control unit 55 monitors the voltage value measured by the voltage measurement part 512 and controls the capacitance value of the capacitor VC1 to be constantly minimum.

When the minimum value of Vpp is about 1,550V as an example, the capacitance value of VC1 was about 35.3 pF and the etching rate was 280 nm/min.

It should be noted that it has been confirmed that when the voltage value Vpp measured by the voltage measurement part 512 takes the minimum value, a capacitance value of a matching element constituting the impedance matching circuit 511 and a capacitance value of a matching element constituting the impedance matching circuit in the second high-frequency power supply circuit 52 both take extrema. That is, it can be said that the voltage value Vpp taking the minimum value is equivalent to the capacitance values of the matching elements of the high-frequency power supply circuits 51 and 52 taking extrema. Therefore, the capacitance value of the capacitor VC1 may be adjusted so that the capacitance values of the matching elements take extrema instead of adjusting the capacitance value of the capacitor VC1 so that the voltage value Vpp becomes minimum.

With the plasma processing apparatus according to the present embodiment configured in the above-mentioned manner, the resonant circuit 53 whose resonant frequency is the second frequency (27 MHz) is connected between the power supply line 510 connecting the stage 20 and the first high-frequency power supply circuit 51 and the ground potential, and therefore the impedance between the counter electrode 30 and the stage 20 decreases and the plasma current flowing to the stage 20 from the counter electrode 30 easily flows. Accordingly, the formation region of the plasma generated on the side of the counter electrode 30 expands, and therefore the processing speed (etching rate) can increase.

FIG. 5 shows an experimental result showing a relationship between the etching rate and the power of the second high-frequency power supply RF2 (27 MHz), comparing a case where the resonant circuit 53 is provided with a case where the resonant circuit 53 is not provided. Here, in both cases, experiments were conducted by the apparatus in which the earth shield 61 is provided and the power range was set to 500 W to 4 KW and the processing pressure was set to 10 Pa. As shown in the figure, in accordance with the present embodiment in which the resonant circuit 53 is provided, the rate of increase in the etching rate with respect to an increase in input power can increase as compared to the case where the resonant circuit 53 is not provided. That is, the figure shows that the formation region of the plasma expanded to the vicinity of the surface of the substrate W due to the provided resonant circuit 53 and it largely contributed to an increase in processing speed.

In addition, in accordance with the present embodiment, the high-frequency voltage at the first frequency (2 MHz) input to the stage 20 is measured and the capacitance value of the capacitor VC1 of the resonant circuit 53 is controlled so that the high-frequency voltage becomes minimum, and therefore the etching processing of the substrate W can continue with the maximum etching rate kept.

Although the embodiment of the present invention has been described hereinabove, the present invention is not limited to such an embodiment and various modifications can be made as a matter of course.

For example, in the above-mentioned embodiment, the frequency (first frequency) of the high-frequency voltage input to the stage 20 is set to 2 MHz and the frequency (second frequency) of the high-frequency voltage input to the counter electrode 30 is set to 27 MHz, though not limited thereto. For example, the first frequency may be less than 13.56 MHz and the second frequency may be 13.56 MHz or more. Also in this case, the reactance value of the coil L and/or the capacitance value of the capacitor VC1 is set so that the resonant frequency of the resonant circuit 53 becomes the second frequency.

Moreover, in the above-mentioned embodiment, the high-frequency voltage Vpp at the first frequency input to the stage 20 is monitored and the capacitance value of the capacitor VC1 in the resonant circuit 53 is adjusted so that its value becomes minimum. Alternatively, a variable coil whose inductance value can be adjusted may be employed as the coil L and the inductance value of the coil L may be adjusted so that the bias voltage Vpp becomes minimum. Also with such a configuration, actions and effects similar to those described above can be obtained.

In addition, in the above-mentioned embodiment, the etching apparatus has been described as an example of the plasma processing apparatus. Alternatively, the present invention can also be applied to a deposition apparatus such as a CVD apparatus or a sputtering apparatus. In this case, a process gas (reactant gas or sputtering argon gas) for deposition is supplied into the vacuum chamber 10 from the gas supply line 43 and the capacitance value of the resonant circuit 53 is adjusted so that the bias voltage becomes minimum. In this manner, the amount of ions input to a substrate as a deposition target can be maximized, and effects such as coverage improvement in holes-filling deposition can be obtained.

### REFERENCE SIGNS LIST

10 vacuum chamber
20 stage
30 counter electrode
43 gas supply line
51 first high-frequency power supply circuit
52 second high-frequency power supply circuit
55 control unit
61 earth shield
100 plasma processing apparatus
510 power supply line
511 impedance matching circuit
512 voltage measurement part
513 resonant circuit

1. A plasma processing apparatus, comprising:
a vacuum chamber;
a substrate-supporting stage that is disposed inside the vacuum chamber and is connected to a first high-frequency power supply circuit that supplies a high-frequency power at a first frequency;
a counter electrode that is disposed in opposite to the stage and is connected to a second high-frequency power supply circuit that supplies a high-frequency power at a second frequency; and
a resonant circuit that is connected between a power supply line for connecting the stage and the first high-frequency power supply circuit and a ground potential and allows high-frequency current at the second frequency from the counter electrode to pass therethrough.

2. The plasma processing apparatus according to claim 1, wherein
the resonant circuit is adjusted so that a resonant frequency between a substrate surface on the stage to the ground potential is the second frequency.

3. The plasma processing apparatus according to claim 1, wherein
the resonant circuit is an LC series resonant circuit including a coil and a capacitor.

4. The plasma processing apparatus according to claim 3, wherein
the first high-frequency power supply circuit includes
an impedance matching circuit that is connected to a first high-frequency power supply,
a filter circuit that shields an input with the high-frequency power at the second frequency that is applied to the power supply line, and
a voltage measurement part that is connected between the impedance matching circuit and the filter circuit and measures a high-frequency voltage that is output to the stage from impedance matching, and
the resonant circuit is connected to the power supply line between the stage and the filter circuit.

5. The plasma processing apparatus according to claim 4, wherein
the capacitor is a variable capacitor capable of adjusting a capacitance value, the plasma processing apparatus further comprising
a control unit that controls a capacitance value of the capacitor so that a voltage value measured by the voltage measurement part becomes minimum.

6. The plasma processing apparatus according to claim 1, further comprising
an earth shield provided between a peripheral surface of the counter electrode and an inner wall surface of the vacuum chamber.

7. The plasma processing apparatus according to claim 1, wherein
the second frequency is a frequency higher than the first frequency.

8. The plasma processing apparatus according to claim 1, further comprising
a gas supply line for supplying an etching gas or a gas for deposition into the vacuum chamber.

9. A control method for the plasma processing apparatus according to claim 1, the resonant circuit being an LC series resonant circuit including a coil and a variable capacitor, comprising:
measuring a high-frequency voltage at the first frequency that is input to the stage; and
controlling a capacitance value of the variable capacitor so that the high-frequency voltage becomes minimum.
